(19) United States
(12) Patent Application Publication
(10) Pub. No.: US 2005/0172991 A1
(43) Pub. Date: Aug. 11, 2005

(54) Thermoelectric element and electronic component module and portable electronic apparatus using it

(75) Inventors: Tomohisa Arai, Yokohama-shi (JP); Takashi Rokutanda, Yokohama-shi (JP); Masami Okamura, Yokohama-shi (JP)

Correspondence Address: FOLEY AND LARDNER;SUITE 500, 3000 K STREET NW, WASHINGTON, DC, 20007, US

(73) Assignee: Kabushiki Kaisha Toshiba

(21) Appl. No.: 10/518,399

(22) PCT Filed: Jun. 18, 2003
(86) PCT No.: PCT/JP03/07701

(51) Int. Cl. H01L 35/28; H01L 35/30

(52) U.S. Cl. 136/205; 136/212

(57) ABSTRACT

A thermoelectric element (1) comprises N type thermoelectric semiconductors (4) and P type thermoelectric semiconductors (5) arranged between support members (2, 3). The N type and P type thermoelectric semiconductors (4, 5) are connected together in series by heat absorbing electrodes (6) and heat radiating electrodes (7) joined to the ends of these semiconductors. First heat transmitting members (8) are integrally provided to the heat radiating electrodes (7), and second heat transmitting members (9) are integrally provided to the heat absorbing electrodes (6) and are allowed to protrude in the same direction as (in a direction opposite to) the direction of the first heat transmitting members (8). The second heat transmitting members (9) function as heat radiating media when the thermoelectric element (1) is not in operation to dissipate the heat of a component (16) to be cooled into a radiation space via the second heat transmitting members (9).

### TECHNICAL FIELD

The present invention relates to a thermoelectric element using thermoelectric semiconductors, and an electronic component module and a portable electronic apparatus using it.

### BACKGROUND ART

Thermoelectric elements using thermoelectric semiconductors of bismuth (Bi)—tellurium (Te) system, ferrum (Fe)—silicon (Si) system, cobalt (Co)—antimony (Sb) system and the like are used as cooling or heating devices, power generating elements and the like. Various kinds of devices using thermoelectric elements utilize the Peltier effect or the Seebeck effect of the thermoelectric semiconductor.

A thermoelectric element is compact and thin, and is capable of carrying out cooling without using a heat medium (refrigerant or the like) of liquid, gas or the like, and therefore, it is used as a cooling device and a heating device in various kinds of fields including temperature control of a cool storing device and a semiconductor manufacturing apparatus. Recently, it also attracts attention as a cooling device for a CPU and the like of a computer.

The thermoelectric element has a thermoelectric semiconductor group in which, for example, N type thermoelectric semiconductors and P type thermoelectric semiconductors are alternately arranged. These N type and P type thermoelectric semiconductors are connected together in series by an electrode disposed at one end side and an electrode disposed at the other end side. When a direct-current is passed into the thermoelectric semiconductor group in such a thermoelectric element, heat absorption occurs due to the Peltier effect at the electrode (heat absorbing electrode) side where electric current flows from the N type thermoelectric semiconductor to the P type thermoelectric semiconductor. Heat radiation (heat generation) occurs at the electrode (heat radiating electrode) side where electric current flows from the P type thermoelectric semiconductor to the N type thermoelectric semiconductor. Accordingly, the object to be cooled (various kinds of members, components, devices and the like) is cooled by being placed at the heat absorbing side of the thermoelectric element.

As a concrete structure of the thermoelectric element, for example, π type structures as shown as follows are known (refer to, for example, see Japanese Patent Laid-open Application No. 9-298319, Japanese Patent Laid-open Application No. 2001-332773, and the like). Namely, as a support member, a ceramics substrate or the like on which a first metal electrode group is formed is used. On the first metal electrode group, N type thermoelectric semiconductors and P type thermoelectric semiconductors are alternately disposed. A second metal electrode group is disposed at upper end sides of the N type thermoelectric semiconductors and the P type thermoelectric semiconductors. Each of the metal electrodes and the N type and P type thermoelectric semiconductors are joined so that all the thermoelectric semiconductors are electrically connected in series.

When the thermoelectric element described above is used as a cooling device for high-temperature heat generating components such as a CPU, the support member at the heat absorption side of the thermoelectric element is fitted on the top face of the heat generating component as described in, for example, Japanese Patent Laid-open Application No. 9-298319. A heat sink, a heat radiating fin and the like are fitted on the support member at the heat radiation side of the thermoelectric element. A module structure which quickly dissipates the heat absorbed from these heat generating components is adopted.

When the thermoelectric element is always in operation, cooling of the semiconductor component can be favorably carried out with the above-described module structure. However, since the semiconductor components such as a CPU differs in heat generation amount in accordance with load, the cooling device using the conventional heat radiating fan or the like does not operate the heat radiating fan at the time of low temperature to save electric power, and operates the heat radiating fan after the high temperature heat generation state is established in some cases. Especially in a personal computer (PC) such as a notebook-type PC (a mobile PC), such an operation rule is adopted in many cases.

When the operation rule of the cooling device as described above is also applied to the thermoelectric element, the thermoelectric element itself becomes a factor of inhibiting the heat transmission by contraries when the thermoelectric element is not in operation. Namely, the thermoelectric element which exists between the heat radiating member such as a heat sink or a heat radiating fin, and a semiconductor component becomes a factor of inhibiting heat transmission to the heat radiating member from the semiconductor component (heat generating component) when the thermoelectric element is not in operation. The thermoelectric semiconductors constituting a thermoelectric element, which are represented by Bi—Te system, significantly inhibit heat transmission since they are generally low in thermal conductivity.

When the operational environment for operating the thermoelectric element only when the heat generation amount from the object to be cooled such as a semiconductor component increases is set as above, the thermoelectric element becomes the factor of inhibiting the heat transmission at the non-operating time such as non-energized time or at the time of failure. Therefore, in the state in which the thermoelectric element is not in operation, the problem of reducing the cooling efficiency of the object to be cooled occurs by contraries, as compared with the structure which does not use the thermoelectric element. On the other hand, when the thermoelectric element is always in operation, power consumption of the thermoelectric element becomes a problem as a matter of course.

In Japanese Patent Laid-open Application No. 5-63244, Japanese Patent Laid-open Application No. 7-131077 and Japanese Patent Laid-open Application No. 7-297453, the thermoelectric exchanging apparatuses each having a heat absorbing heat exchange plate (heat absorbing fin) provided integrally with the heat absorbing electrode and a heat releasing heat exchange plate (heat releasing fin) provided integrally with the heat radiating electrode are described. In this thermoelectric exchanging apparatus, the heat absorbing fin and the heat releasing fin are allowed to protrude respectively in the different directions with respect to the thermoelectric semiconductor group.

The heat absorbing fin and heat releasing fin in the above-described thermoelectric exchanging apparatus respectively construct the heat exchanging parts. A fluid to be cooled which is cooled in the thermoelectric exchanging apparatus contacts the heat absorbing fin. A cooling fluid which cools the thermoelectric exchanging apparatus itself contacts the heat releasing fin. Among these heat exchanging fins, the heat absorbing fin is absolutely a heat absorbing heat exchanger which absorbs the heat of the fluid to be cooled, and is not intended for the other use.

An object of the present invention is to provide a thermoelectric element restrained in reduction of the cooling characteristic of an object to be cooled at a non-operating time such as a non-energized time or time of failure in cooling an object to be cooled such as a CPU of a computer, for example, by using the thermoelectric element. Another object of the present invention is to provide an electronic component module which makes it possible to restrain reduction of the cooling characteristic of the object to be cooled when the thermoelectric element is not in operation while keeping the cooling characteristic at the time when the thermoelectric element is in operation by using such a thermoelectric element, and a portable electronic apparatus using it.

### DISCLOSURE OF THE INVENTION

A thermoelectric element of the present invention comprises a thermoelectric semiconductor group having N type thermoelectric semiconductors and P type thermoelectric semiconductors, heat absorbing electrodes joined to one end part of the thermoelectric semiconductor group, heat radiating electrodes joined to the other end part of the thermoelectric semiconductor group so that at least parts of the N type thermoelectric semiconductors and the P type thermoelectric semiconductors are alternately connected in series, and heat transmitting members integrally provided to the respective heat absorbing electrodes and heat radiating electrodes, disposed to be in contact with a cooling medium and having a function of radiating heat to the cooling medium.

In the thermoelectric element of the present invention, not only the heat radiating electrodes but also the heat absorbing electrodes are provided with the heat transmitting members which function as the heat radiating media. The heat transmitting members provided at the heat absorbing electrodes are disposed in the radiation space where the cooling medium exists without the thermoelectric semiconductors therebetween. Since this heat transmitting member functions as the heat radiating media when the thermoelectric element is not in operation, the heat radiating performance of the object to be cooled when the thermoelectric element is not in operation can be enhanced. Accordingly, it is possible to keep the cooling characteristic of the object to be cooled when the thermoelectric element is not in operation without reducing the cooling characteristic when the thermoelectric element is energized and operated.

Another thermoelectric element of the present invention is characterized by comprising a support member, a thermoelectric semiconductor group having N type thermoelectric semiconductors and P type thermoelectric semiconductors arranged along the support member, heat absorbing electrodes joined to one end part of the thermoelectric semiconductor group, heat radiating electrodes joined to the other end part of the thermoelectric semiconductor group so that at least parts of the N type thermoelectric semiconductors and the P type thermoelectric semiconductors are alternately connected in series, and first heat transmitting members integrally provided to the heat radiating electrodes, and provided to protrude to a radiation space, and second heat transmitting members integrally provided to the heat absorbing electrodes, and provided to protrude to the radiation space in a same direction as the first heat transmitting members.

In the above-described thermoelectric element, the second heat transmitting members allowed to protrude in the same direction as the first heat transmitting members are provided at the heat absorbing electrodes. The second heat transmitting members are located in the same radiation space as the first heat transmitting members provided at the heat radiating electrodes. The second heat transmitting members function as the heat radiating media when the thermoelectric element is not in operation. By such second heat transmitting member, the heat radiation performance of the object to be cooled when the thermoelectric element is not in operation can be enhanced. Accordingly, it is possible to keep the cooling characteristic of the object to be cooled when the thermoelectric element is not in operation without reducing the cooling characteristic when the thermoelectric element is energized and operated.

Still another thermoelectric element of the present invention is characterized by comprising a support member, a thermoelectric semiconductor group having N type thermoelectric semiconductors and P type thermoelectric semiconductors arranged along the support member, heat absorbing electrodes joined to one end part of the thermoelectric semiconductor group, heat radiating electrodes joined to the other end part of the thermoelectric semiconductor group so that at least parts of the N type thermoelectric semiconductors and the P type thermoelectric semiconductors are alternately connected in series, first heat transmitting members integrally provided to the heat radiating electrodes, and provided to protrude outside the heat radiating electrodes to be located at a first radiation space, second heat transmitting members integrally provided to the heat absorbing electrodes, and provided to protrude outside the heat absorbing electrodes to be located in a second radiation space, and a heat absorbing member connected to end portions at an opposite side from the heat absorbing electrodes, of the second heat transmitting members to be capable of transmitting heat, and constituting a contact part with an object to be cooled.

In the above-described thermoelectric element, the second heat transmitting members which are allowed to protrude outside the heat absorbing electrodes are provided at the heat absorbing electrodes. The second heat transmitting members are allowed to protrude in the different direction from the first heat radiating electrodes provided at the heat radiating electrodes, and are located in the second radiation space. The second heat transmitting members functions as the heat radiating media when the thermoelectric element is not in operation. By such second heat transmitting members, heat radiating performance of the object to be cooled when the thermoelectric element is not in operation can be enhanced. Accordingly, it is possible to keep the cooling characteristic of the object to be cooled when the thermoelectric element is not in operation without reducing cooling characteristic when the thermoelectric element is energized and operated.

### BRIEF DESCRIPTION OF DRAWINGS

FIG. 1 is a sectional view showing a schematic structure of a thermoelectric element according to a first embodiment of the present invention.

FIG. 2 is a view showing one example of an arrangement structure of a thermoelectric semiconductor group in the thermoelectric element shown in FIG. 1.

FIG. 3 is a view showing another example of the arrangement structure of the thermoelectric semiconductor group in the thermoelectric element shown in FIG. 1.

FIG. 4 is a perspective view showing one constitution example of members formed by integrating electrodes and heat transmitting members used in the thermoelectric element shown in FIG. 1.

FIG. 5 is a perspective view showing another constitution example of the members formed by integrating the electrodes and the heat transmitting members used in the thermoelectric element shown in FIG. 1.

FIG. 6 is a sectional view showing a first modification example of the thermoelectric element shown in FIG. 1.

FIG. 7 is a sectional view showing a second modification example of the thermoelectric element shown in FIG. 1.

FIG. 8 is a sectional view showing another constitution example of the heat transmitting members used in the thermoelectric element of the present invention.

FIG. 9 is a sectional view showing still another constitution example of the heat transmitting member used in the thermoelectric element of the present invention.

FIG. 10 is a sectional view showing a schematic structure of a thermoelectric element according to a second embodiment of the present invention.

FIG. 11 is a sectional view showing a schematic structure of a thermoelectric element according to a third embodiment of the present invention.

FIG. 12 is a sectional view showing a modification example of the thermoelectric element shown in FIG. 11.

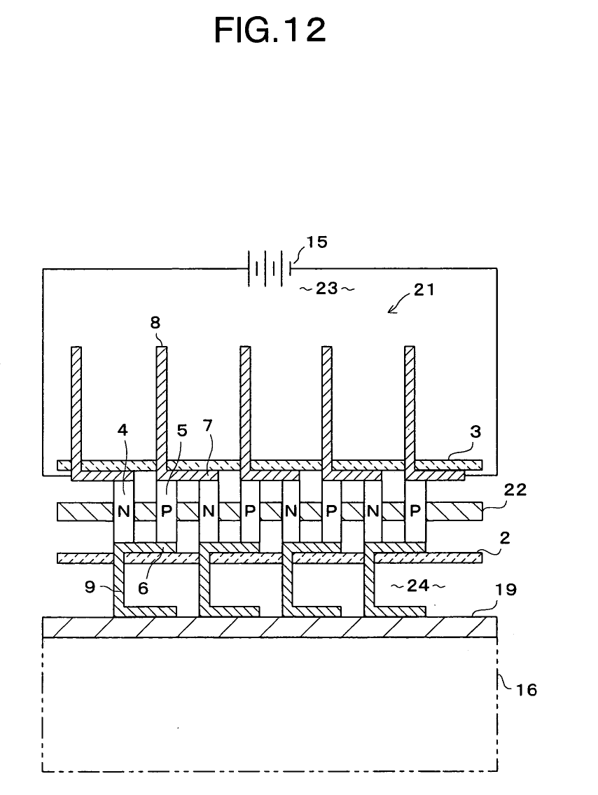

FIG. 13 is a sectional view showing a schematic structure of a thermoelectric element according to another embodiment of the present invention.

### BEST MODE FOR IMPLEMENTING THE INVENTION

Hereinafter, a mode for carrying out the present invention will be explained.

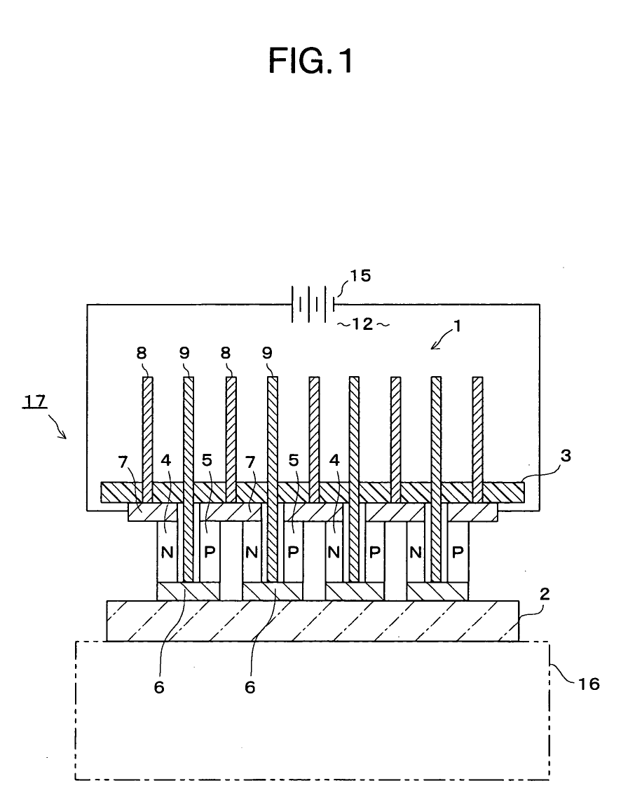

FIG. 1 is a sectional view schematically showing a rough structure of a thermoelectric element according to a first embodiment of the present invention. A thermoelectric element 1 shown in the drawing has support members 2 and 3 up and down, and the lower support member 2 and the upper support member 3 are disposed to oppose to each other. The thermoelectric element 1 in this embodiment has a heat absorption surface on the side of the lower support member 2 and a heat radiation surface on the side of the upper support member 3. Namely, the lower support member 2 is the heat absorption side support member, and the upper support member 3 is the heat radiation side support member. The heat absorption side support member 2 constitutes a contact part with an object to be cooled which will be described later.

The heat radiation side support member 3 is not always necessary and can be omitted. The placement position of the heat radiation side support member 3 is not specially limited, and it is possible to apply the placement that will be described later. Further, the support members are not limited to a pair of upper and lower support members 2 and 3, but it is possible to support the element structure with one support member. Such element structure will be described in detail later.

Of the aforementioned support members 2 and 3, the heat absorption side support member (lower support member) 2 functions as a structure supporter of the thermoelectric element 1, and an insulating ceramics substrate such as, for example, an alumina substrate, an aluminum nitride substrate, or a silicon nitride substrate, is preferably used. The aluminum nitride substrate with high thermal conductivity is especially effective as a construction material of the heat absorption side support member 2.

A ceramics substrate being an insulating substrate can be used for the heat radiation side support member (upper support member) 3 as the heat absorption side support member 2. Further, if it is possible to support the entire element structure with the heat absorption side support member 2, it is preferable to apply an insulating resin substrate, an insulating resin film or the like to the heat radiation side support member 3. These resin members are excellent in workability, and therefore, manufacture of the thermoelectric element l is facilitated.

A plurality of N type thermoelectric semiconductors 4 and a plurality of P type thermoelectric semiconductors 5 are alternately arranged between the heat absorption side support member 2 and the heat radiation side support member 3, and these semiconductors are disposed in a matrix form and construct a thermoelectric semiconductor group as the whole element. In other words, the N type thermoelectric semiconductors 4 and the P type thermoelectric semiconductors 5 are alternately arranged along one main surface of the heat absorption side support member 2.

Various kinds of known materials can be used for the thermoelectric semiconductors 4 and 5, and as a representative example, a Bi—Te system thermoelectric semiconductor can be cited. As a Bi—Te system semiconductor, a compound semiconductor including at least one kind of element selected from Bi and Sb, and at least one kind of element selected from Te and Se as essential elements and further including an additive element such as I, Cl, Br, Hg, Au, Cu or the like in accordance with necessity is known. For the thermoelectric semiconductors 4 and 5, such Bi—Te system thermoelectric semiconductors are preferable.

The thermoelectric semiconductors 4 and 5 are not limited to the above-described Bi—Te system thermoelectric semiconductors, but, for example, Fe—Si system thermoelectric semiconductors, Co-Sb system thermoelectric semiconductors and the like can be applied. Further, it is possible to use various kinds of semiconductors exhibiting the Peltier effect based on the combination of N type and P type, such as Fe—Mn system half-Heusler alloy, for the thermoelectric semiconductors 4 and 5.

A plurality of N type thermoelectric semiconductors 4 and P type thermoelectric semiconductors 5 are electrically connected in series by the heat absorbing electrodes 6 provided on the heat absorption side support member 2, and the heat radiating electrodes 7 provided on the heat radiation side support member 3 so that direct-current flows through the N type thermoelectric semiconductor 4, the P type thermoelectric semiconductor 5, the N type thermoelectric semiconductor 4, the P type thermoelectric semiconductor 5 in this order. A plurality of heat absorbing electrodes 6 and heat radiating electrodes 7 respectively constitute electrode groups. Each of the electrodes 6 and 7 can be constructed by a metal plate such as, for example, a copper plate and an aluminum plate.

A plurality of heat absorbing electrodes 6 are provided on a surface of the heat absorption side support member 2. On the other hand, a plurality of heat radiating electrodes 7 are disposed on the heat radiation side support member 3. The heat absorbing electrode 6 has a shape for connecting the N type thermoelectric semiconductor 4 and the P type thermoelectric conductor 5 adjacent to each other in series in this order. In the heat absorbing electrode 6, heat absorption occurs based on this connection order of the thermoelectric semiconductors 4 and 5. Meanwhile, the heat radiating electrode 7 has a shape for connecting the P type thermoelectric semiconductor 5 and the N type thermoelectric semiconductor 4 adjacent to each other in series in this order except for the electrodes (lead leader electrodes) at both end portions. In the heat radiating electrode 7, heat radiation (heat generation) occurs based on this connection order of the thermoelectric semiconductors 5 and 4.

Lower side end portions (heat absorbing side portions) of the N type thermoelectric semiconductor 4 and P type thermoelectric semiconductor 5 are respectively joined to the heat absorbing electrode 6 via a solder layer not shown, for example. Upper side end portions (heat radiating side portions) of the N type thermoelectric semiconductor 4 and the P type thermoelectric semiconductor 5 are similarly joined to the heat radiating electrode 7 via a solder layer not shown. By connecting the N type thermoelectric semiconductors 4 and the P type thermoelectric semiconductors 5 adjacent to each other are connected in order by the heat absorbing electrodes 6 and the heat radiating electrodes 7, the structure, in which a plurality of N type thermoelectric semiconductors 4 and a plurality of P type thermoelectric semiconductors 5 are alternately connected in series when they are seen as the whole thermoelectric element 1, is formed.

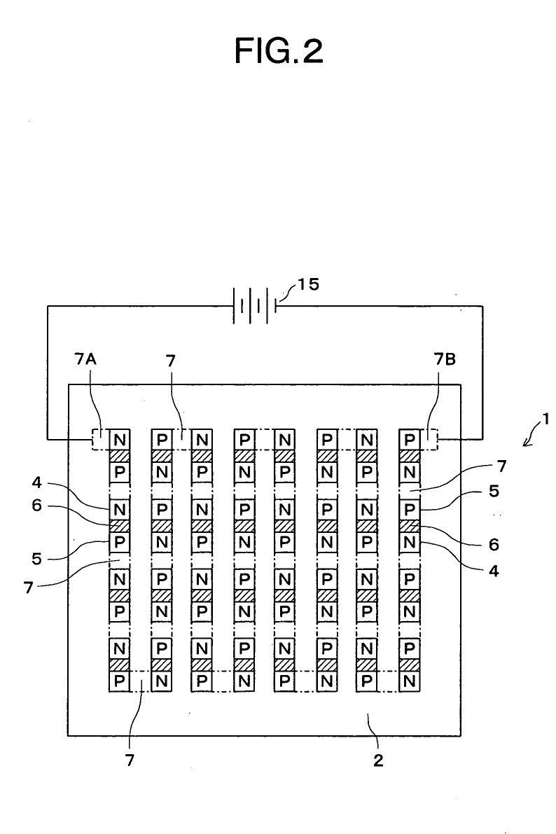

As an arrangement structure of the thermoelectric semiconductor group, the structure in which a plurality of N type thermoelectric semiconductors 4 and a plurality of P type thermoelectric semiconductors 5 are disposed on the heat absorbing side support member 2 in a turn-back state so that a plurality of N type thermoelectric semiconductors 4 and a plurality of P type thermoelectric semiconductors 5 are alternately connected in series is adopted, for example, as shown in FIG. 2. In the arrangement structure of the thermoelectric semiconductor group shown in FIG. 2, all the N type thermoelectric semiconductors 4 and P type thermoelectric semiconductors 5 are alternately connected in series.

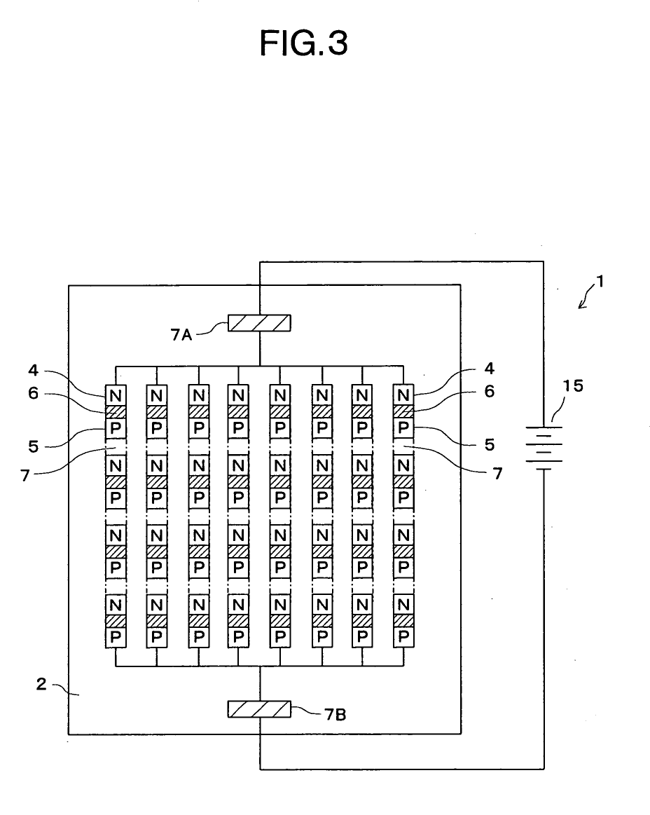

It is suitable that at least a part of the thermoelectric semiconductor group is connected in series, and it is possible to apply the arrangement structure as shown in, for example, FIG. 3. FIG. 3 shows a structure in which a plurality of columns each having the N type thermoelectric semiconductors 4 and the P type thermoelectric semiconductors 5 alternately connected in series are disposed. A plurality of thermoelectric semiconductor columns are connected in parallel with respect to lead leader electrodes 7A and 7B. According to the element structure in which a plurality of thermoelectric semiconductor columns are connected in parallel like this, even if a poor connection, failure or the like occurs to any thermoelectric semiconductor column, the operation environment is kept for the other thermoelectric semiconductor columns. The arrangement shown in FIG. 2 is more excellent in the cooling efficiency or the like, but the arrangement in FIG. 3 contributes enhancement in reliability of the thermoelectric element 1.

A first heat transmitting member 8 is integrally provided at each of the heat radiating electrode 7 constituting the heat radiation side electrode group. The first heat transmitting member 8 is provided to extend in a substantially perpendicular direction with respect to a back surface (an opposite surface from a joint surface to the thermoelectric semiconductors 4 and 5) of the heat radiating electrode 7. The first heat transmitting member 8 is integrally formed with the heat radiating electrode 7 so as not to inhibit heat transmission to and from the heat radiating electrode 7. The heat radiating electrode 7 and the first heat transmitting member 8 are thermally integrated.

Likewise, a second heat transmitting member 9 is integrally provided at each of the heat absorbing electrodes 6 constituting the heat absorbing side electrode group. The second heat transmitting member 9 is provided to extend in the substantially perpendicular direction with respect to a surface (joint surface to the thermoelectric semiconductors 4 and 5) of the heat absorbing electrode 6. The second heat transmitting member 9 is integrally formed with the heat absorbing electrode 6 so as not to inhibit heat transmission to and from the heat absorbing electrode 6. The heat absorbing electrode 6 and the second heat transmitting member 9 are thermally integrated. It is preferable that these heat transmitting members 8 and 9 are constituted of a metal material excellent in thermal conductivity such as, for example, copper, aluminum, or alloys of them.

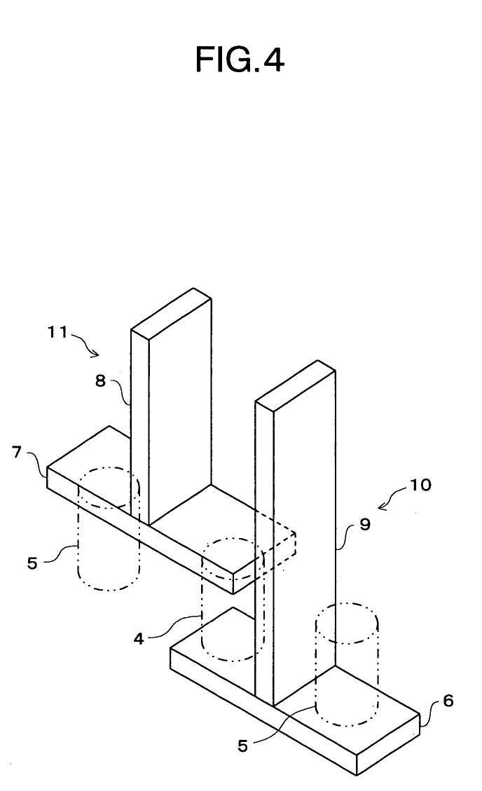

FIG. 4 shows one constitution example of a member 10 formed by integrating the heat absorbing electrode plate 6 and the second heat transmitting member 9 and a member 11 formed by integrating the heat radiating electrode 7 and the first heat transmitting member 8. These heat absorption side member 10 and heat radiation side member 11 both have T-shapes, and the heat absorption side member 10 has a structure in which the plate-shaped second heat transmitting member 9 is integrally provided to protrude on the surface of the heat absorbing electrode plate 6. The heat radiation side member 11 has a structure in which the plate-shaped first heat transmitting member 8 is integrally provided to protrude on the back surface of the heat radiating electrode 7.

Various kinds of methods can be applied for integration of these electrode plates 6 and 7 and heat transmitting members 9 and 8, if only the methods do not inhibit heat transmission. For example, the electrode plates 6 and 7 and the heat transmitting members 9 and 8 can be integrated by using a joining method such as soldering, and welding. The absorption side member 10 and the heat radiation side member 11 having a T-shape, an L-shape or the like may be formed by machine work, deformation processing or the like.

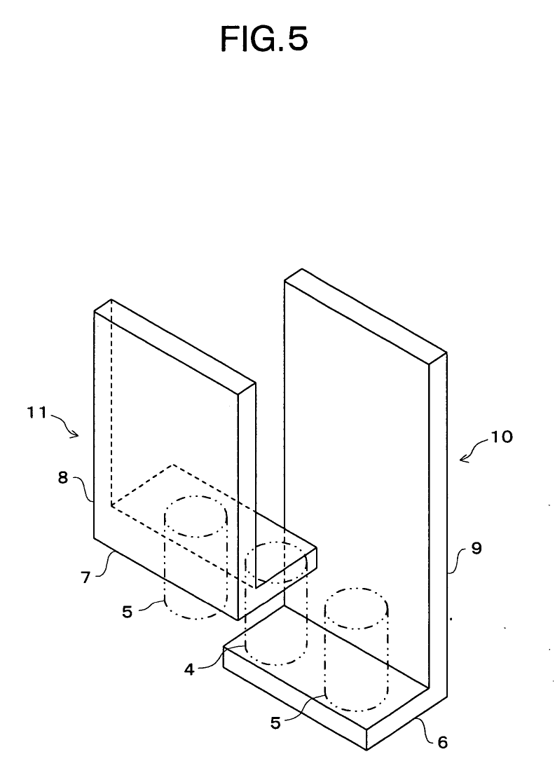

The shapes of the heat absorption side member 10 and the heat radiation side member 11 are not limited to the T-shapes. Various kinds of shapes can be applied, if only they are the shapes in which the electrode plates 6 and 7 and the heat transmitting members 9 and 8 are integrated and the heat transmitting members 9 an 8 are provided to protrude. FIG. 5 shows the heat absorption side member 10 and the heat radiation side member 11 having the shapes in which the plate-shaped heat transmitting members 9 and 8 are provided to protrude in the L-shape with respect to the electrode plates 6 and 7. In this manner, the integrated shapes of the electrode plates 6 and 7 and the heat transmitting members 9 and 8 can be properly selected.

The first heat transmitting member 8 integrated with the heat radiating electrode 7 and the second heat transmitting member 9 integrated with the heat absorbing electrode 6 are respectively provided to protrude outside the heat radiating electrode 7, further to a space 12 outside the heat radiation side support member 3. The space 12 is a radiation space in which a cooling medium exists. More specifically, cooling fluid such as air flows in the radiation space 12. The cooling medium is not limited to air, but inert gas, or liquid or the like according to the circumstances, can be applied. The first and second heat transmitting members 8 and 9 are disposed in the radiation space 12 to be in contact with the cooling fluid. In this radiation space 12, the first and second heat transmitting members 8 and 9 function as the heat radiating media.

As describe above, the second heat transmitting member 9 is provided to protrude in the same direction as the first heat transmitting member 8. Heat occurring to the heat radiating electrode 7 is dissipated into the radiation space 12 via the first heat transmitting member 8. Likewise, the heat transmitted to the heat absorbing electrode 6 (which will be described in detail later) is dissipated into the radiation space 12 via the second heat transmitting member 9. The first heat transmitting member 8 and the second heat transmitting member 9 respectively reach the radiation space 12 via through holes provided in the heat radiation side support member 3.

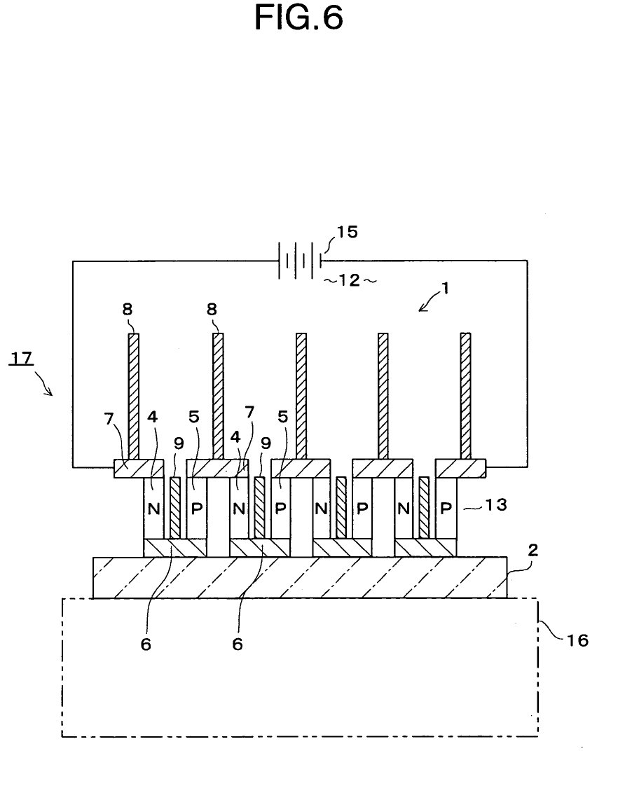

FIG. 1 shows an element structure in which the second heat transmitting members 9 integrated with the heat absorbing electrodes 6 are disposed at the radiation space 12 outside the heat radiation side support member 3. The second heat transmitting members 9 may be disposed in a space 13 inside the heat radiating electrodes 7 as shown in FIG. 6, for example. This space 13 is a space where the N type thermoelectric semiconductors 4 and the P type thermoelectric semiconductors 5, and cooling fluid flows in such space 13. The space 13 functions as the heat radiation space as the space 12, and the second heat transmitting member 9 functions as a heat radiating medium in the radiation space 13.

However, in order to enhance the cooling efficiency by the second heat transmitting member 9, it is preferable to dispose the second heat transmitting member 9 to reach the radiation space 12 outside the radiation side support member 3. FIG. 6 shows an element structure in which the radiation side support member 3 is omitted. Like this, the thermoelectric element 1 does not necessarily require the radiation side support member 3. The thermoelectric element 1 shown in FIG. 6 keeps an element structure with only the absorption side support member.

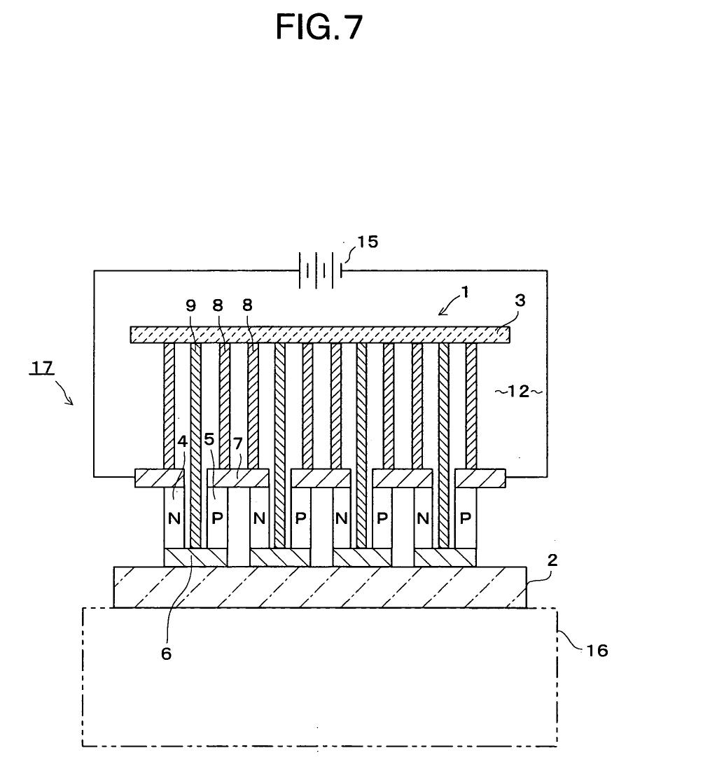

The number of heat transmitting members 8 and 9 to be placed is not limited to one for each of the electrode plates 6 and 7. For example, as shown in FIG. 7, a plurality of heat transmitting members may be placed at one electrode plate. This can further enhance heat radiation characteristic. FIG. 7 shows the state in which two of the first heat transmitting members 8 are placed at each heat radiating electrode 7. A plurality of second heat transmitting members 9 can be placed if there is enough space 2.

When a plurality of heat transmitting members are placed at each electrode plate, integrated members (the absorption side member 10 and the radiation side member 11) each having a U-shape or a concave shape can be used. FIG. 7 shows an element structure in which the radiation side support member 3 is disposed on the heat transmitting members 8 and 9. Like this, the placement position of the radiation side support member 3 is not specially limited, and it is also possible to omit it as described above.

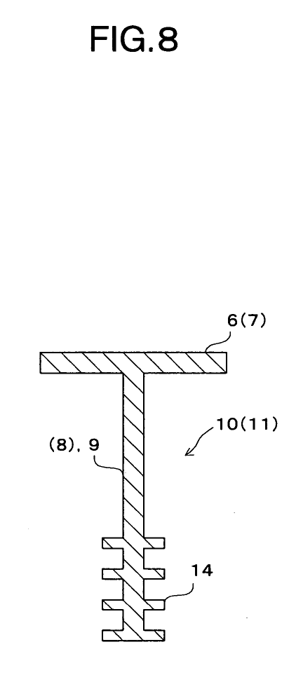

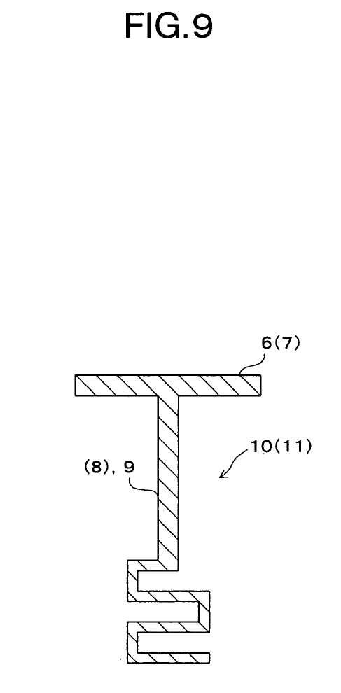

The shapes of the heat transmitting members 8 and 9 which function as the heat radiation media are not limited to the plate shapes as shown in FIGS. 4 and 5. As the shapes of heat radiating portions of the heat transmitting members 8 and 9, the shape which increases the surface area of the parts which are located in the radiation space 12 can be applied. FIG. 8 shows the integrated members 10 and 11 in which an auxiliary fin 14 is provided at the heat radiating part (the part located at the radiation space 12) of each of the heat transmitting members 8 and 9. FIG. 9 shows the integrated members 10 and 11 in which the heat radiating part of each of the heat transmitting member 8 and 9 is formed into a bent shape to increase the surface area. Beside these shapes, various kinds of shapes of the increase in surface area can be applied, and the heat radiation characteristic from the heat transmitting members 8 and 9 can be further enhanced by them.

When a direct-current is passed to the thermoelectric semiconductors 4 and 5 in the aforementioned thermoelectric element 1 from the direct-current power supply 15, heat absorption occurs at the lower end part side of the thermoelectric semiconductors 4 and 5 due to the Peltier effect, and heat radiation occurs at the upper end part side. Namely, heat absorption occurs in the heat absorbing electrode 6 in which the direct-current flows from the adjacent N type thermoelectric semiconductor 4 toward the P type thermoelectric semiconductor 5. On the other hand, heat radiation occurs in the heat radiating electrode 7 in which the direct-current flows from the P type thermoelectric semiconductor 5 toward the N type thermoelectric semiconductor 4.

In the thermoelectric element 1 in this embodiment, the heat absorption side support member 2 is a contact part with the object 16 to be cooled. The heat absorption side support member 2 functions as the heat absorbing member. Accordingly, the thermoelectric element 1 is fitted on the object 16 to be cooled so that the object 16 to be cooled and the heat absorption side support member 2 are in contact with each other. By them, an electric component module 17 having the cooling function is constituted.

As the object 16 to be cooled, high heat generation type of semiconductor components such as a high integration circuit element such as CPU, for example, and a laser element are cited. The object 16 to be cooled is not limited to them, but the thermoelectric element 1 can be applied to various kinds of components and members which require cooling. The thermoelectric element 1 can be particularly preferably used for an electric component which operates the cooling device as necessary as a CPU of a notebook type PC.

In the electronic component module 17 to which the thermoelectric element 1, the thermoelectric element 1 is energized and operated when the heat generation amount of the component 16 to be cooled increases, and the heat of the component 16 to be cooled is absorbed, thereby cooling the component 16 to be cooled. On the other hand, when the heat generation amount of the component 16 to be cooled does not reach such a heat amount as to require operation of the thermoelectric element 1, the passage of the electric current to the thermoelectric element 1 is cut off to bring it out of operation.

In the state in which the thermoelectric element 1 is not in operation, the heat from the component 16 to be cooled is transmitted to the second heat transmitting member 9 via the heat absorption side support member 2 and the heat absorbing electrode 6, and is dissipated from this second heat transmitting member 9 to the radiation space 12 where the cooling fluid flows. In the thermoelectric element 1 shown in FIG. 1, FIG. 6 and FIG. 7, the heat radiation parts of the second heat transmitting members 9 are disposed at the position away from the cooling surfaces of the thermoelectric semiconductors 4 and 5 seen from the component 16 to be cooled.

In the thermoelectric element 1 of this embodiment, the second heat transmitting member 9 directly reaches the radiation space 12 without interposition of the thermoelectric semiconductors 4 and 5 therebetween. Therefore, the heat of the component 16 to be cooled can be directly dissipated into the radiation space 12 via the second heat transmitting member 9 from the heat absorption side support member 2 and the heat absorbing electrode 6. Since the second heat transmitting member 9 functions as the heat radiating medium in this manner when the thermoelectric element 1 is not energized or is failed, the heat radiation performance of the component 16 to be cooled when the thermoelectric element 1 is not in operation can be enhance significantly as compared with the conventional element structure which radiates heat via the thermoelectric semiconductors 4 and 5.

Accordingly, when the thermoelectric element 1 is operated as necessary in accordance with the heat generation amount of the component 16 to be cooled, the cooling characteristic can be kept not only when the thermoelectric element 1 in operation but also when the thermoelectric element 1 is not in operation. The same applies to the time of failure of the thermoelectric element 1. As is described, the thermoelectric element 1 suppresses reduction in the cooling characteristic of the component 16 to be cooled when the thermoelectric element is not in operation. As the accompanying effect, the cost can be reduced by constructing the thermoelectric element and the cooling fin, which are conventionally manufactured and assembled as separate components, to be an integrated component.

The electronic component module 17 to which the thermoelectric element 1 is applied, is preferably used in a portable electronic apparatus such as a notebook type PC (laptop type PC), a tablet PC, a PDA, and a potable telephone. As the embodiment of the portable electronic apparatus of the present invention, various kinds of portable electronic apparatuses such as a notebook type PC, a tablet PC, a PDA and a potable telephone each including the above electronic component module 17 are cited.

The portable electronic apparatus as described above is driven by a battery, and the cooling device attached to the component 16 to be cooled such as a CPU is operated as needed to save electric power. Namely, when the heat generation amount is small, the operation of the cooling device is stopped. In the case where the operation rule of such a cooling device is applied, reduction in the cooling characteristic of the component to be cooled (CPU or the like) at the non-operating time is also suppressed in the thermoelectric element 1, and therefore, it becomes possible to keep the operation characteristic and the like of the portable electronic apparatus stable.

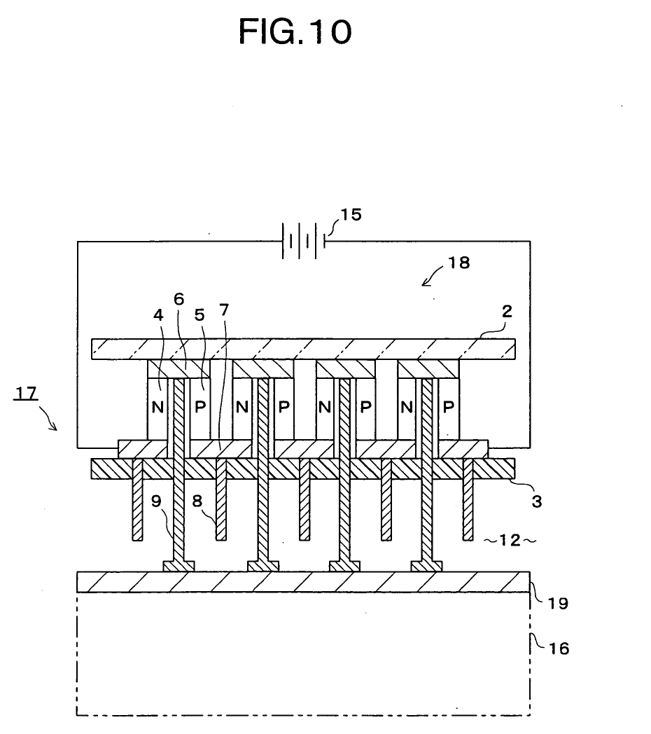

Next, a second embodiment of the present invention will be explained with reference to FIG. 10. A thermoelectric element 18 shown in FIG. 10 has a heat absorbing member 19 provided at end portions of the second heat transmitting member 9, at an opposite side from the heat absorbing electrodes 6. The heat absorbing member 19 becomes a contact part with the component 16 to be cooled. The second heat transmitting members 9 and the heat absorbing member 19 are connected based on a connecting structure capable of keeping favorable heat transmission, in other words, a connecting structure without interposing a member or the like which inhibiting heat transmission therebetween. More specifically, it is preferable to integrate them by the same method as the integration method of the electrode plates 6 and 7 and the heat transmitting members 8 and 9.

The thermoelectric element 18 shown in FIG. 10 has the first and second heat transmitting members 8 and 9 which are provided to project in the same direction with respect to the outside space (radiation space) 12 of the heat radiation side support member 3 as in FIG. 1. The thermoelectric element 18 is fitted so that the heat absorbing member 19 provided at the end portions of the second heat transmitting members 9 abuts to the component 16 to be cooled. The second heat transmitting member 9 has the function as a part of the heat absorbing electrode 6 and the function as the heat radiating medium in combination. The second heat transmitting member 9 is attached to the component 16 to be cooled via the heat absorbing member 19 by being electrically insulated.

The thermoelectric element 18 is disposed so that the heat radiation side support member 3 is located at the component 16 to be cooled side. The thermoelectric element 18 shown in FIG. 10 has the placement structure vertically reversed from FIG. 1. The radiation space 12 where cooling fluid flows is provided between the thermoelectric element 18 and the component 16 to be cooled. In the thermoelectric element 18 shown in FIG. 10, both the heat absorption side support member 2 and the heat radiation side support member 3 can be omitted. FIG. 10 shows an element structure in which the heat radiating portions of the second heat transmitting members 9 are disposed between the component 16 to be cooled and the cooling surfaces of the thermoelectric semiconductors 4 and 5.

In the electronic component module 17 to which the above-described thermoelectric element 18 is applied, the thermoelectric element 18 is energized and operated when the heat generation amount of the component 16 to be cooled increases, and the heat of the component 16 to be cooled is absorbed, thereby cooling the component 16 to be cooled. On this occasion, the second heat transmitting members 9 function as the heat transmitting media (part of the heat absorbing electrodes 6) to the heat absorbing electrodes 6 from the heat absorbing member 19. The component 16 to be cooled is cooled by the thermoelectric element 18 based on the heat transmission structure using the second heat transmitting members 9.

On the other hand, when the heat generation amount of the component 16 to be cooled is small, the passing of the electric current to the thermoelectric element 18 is cut off and the thermoelectric element 18 is out of operation. When the thermoelectric element 18 is in the state in which it is not in operation, the heat of the component 16 to be cooled is directly dissipated from the heat absorbing member 19 and the second heat transmitting members 9 into the radiation space 12 where the cooling fluid flows. In other words, cooling of the component 16 to be cooled in the state in which the thermoelectric element 18 is not in operation carried out by radiating heat into the cooling fluid via the second heat transmitting members 9. The radiation space 12 is a space formed by leg parts when the thermoelectric element 18 is fitted with the second heat transmitting members 9 as the leg parts.

As described above, in the second embodiment, the second heat transmitting member 9 functions as the heat transmitting medium to the heat absorbing electrode 6 from the heat absorbing member 19 when the thermoelectric element 18 is in operation, and functions as the heat radiating medium to the cooling fluid from the heat absorbing member 19 when the thermoelectric element 18 is not in operation. In the thermoelectric element 18 of the second embodiment, the second heat transmitting member 9 functions as the heat radiating medium when the thermoelectric element 18 is not in operation, and therefore, heat radiation performance of the component 16 to be cooled when the thermoelectric element 18 is not in operation is enhanced remarkably as compared with the conventional structure. Accordingly, when the thermoelectric element 18 is made to operate as needed in accordance with the heat generation amount of the component 16 to be cooled, it is possible to keep favorable cooling characteristic.

Further, in the thermoelectric element 18 of the second embodiment, fatigue breakdown or the like based on a thermal expansion difference between the thermoelectric element 18 and the component to be cooled 16 can be suppressed. This is because the thermoelectric element 18 is mounted on the component 16 to be cooled with the second heat transmitting members 9 as the leg portions. Namely, when a thermal operation is repeatedly performed, thermal fatigue based on the thermal expansion difference from the component to be cooled 16 occurs to the thermoelectric element 18, and fatigue breakdown or the like easily occurs. For this point, the restricting force for the thermoelectric element 18 is reduced with flexibility of the second heat transmitting members 9 to relieve the stress concentration, whereby the fatigue breakdown or the like of the thermoelectric element 18 can be suppressed. This contributes to enhancement in reliability of the thermoelectric element 18.

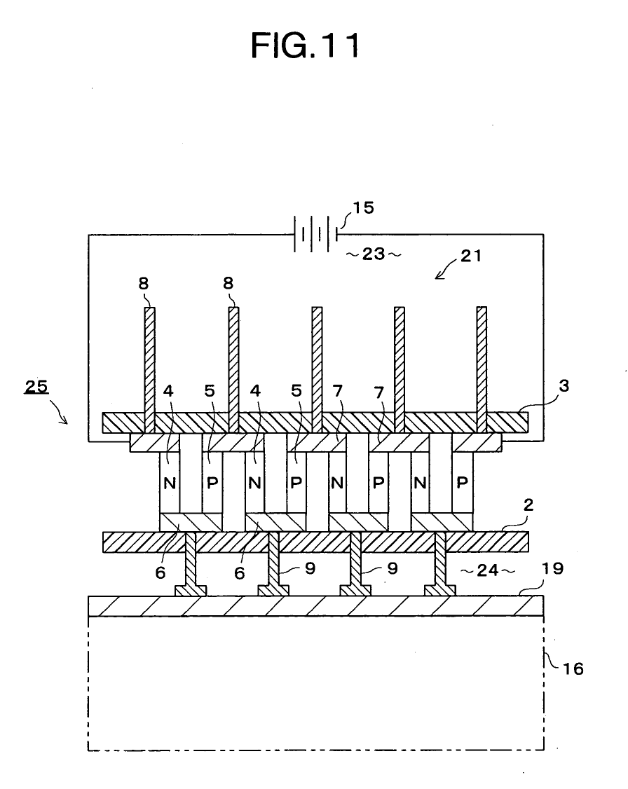

Next, a third embodiment of the present invention will be explained with reference to FIG. 11. The same parts as FIG. 1 are given the same reference numerals and symbols and the explanation of them will be partially omitted. In a thermoelectric element 21 shown in the drawing, a plurality of N type thermoelectric semiconductors 4 and a plurality of P type thermoelectric semiconductors 5 are alternately arranged between the heat absorption side support member 2 and the heat radiation side support member 3. These N type thermoelectric semiconductors 4 and the P type thermoelectric semiconductors 5 are disposed in a matrix form as the whole elements and construct a thermoelectric semiconductor group.

The heat absorption side support member 2 and the heat radiation side support member 3 are not essential in forming the element structure and can be omitted. As a construction material in the case where the heat absorption side support member 2 and the heat radiation side support member 3 are applied, it is preferable to use an insulating resin substrate, an insulating resin film or the like because of workability and the like. Further, the support member (corresponding to the structural support member/the absorption side support member 2 in FIG. 1) 22 for holding the element structure may be disposed at a position between the N type thermoelectric semiconductor 4 and the P type thermoelectric semiconductor 5. In this case, the heat absorption side support member 2 and the heat radiation side support member 3 can be also omitted.

The heat absorbing electrodes 6 are disposed at the heat absorption side support member 2 side. The heat radiating electrodes 7 are disposed at the heat radiation side support member 3 side. By these heat absorbing electrodes 6 and heat radiating electrodes 7, a plurality of N type thermoelectric semiconductors 4 and the P type thermoelectric semiconductors 5 are alternately connected in series. As described above, it is suitable that at least part of the plurality of N type thermoelectric semiconductors 4 and the P type thermoelectric semiconductors 5 are alternately connected in series.

The concrete structures and construction materials of the thermoelectric semiconductors 4 and 5 and the electrodes 6 and 7, the connecting structure of the thermoelectric semiconductors 4 and 5 by the electrodes 6 and 7, and the like are the same as the aforementioned first embodiment. When the supporting state of the thermoelectric semiconductors 4 and 5 by the support members 2 and 3 is insufficient, the thermoelectric semiconductors 4 and 5 may be supported by a calking tool, a case or the like from both sides of the support members 2 and 3. Further, it is also possible to apply such a structure as supports them with a calking tool, a case or the like without using the support members 2 and 3.

Each of the first heat transmitting members 8 is provided integrally at a back surface side of each of the heat radiating electrodes 7 constituting the heat radiation side electrode group. These first heat transmitting members 8 are allowed to protrude to reach the space 23 outside the heat radiation side support member 3. The space 23 constitutes a first radiation space. Similarly, each of the second heat transmitting members 9 which function as part of the heat absorbing electrode 6 is provided integrally at a back surface side of each of the heat absorbing electrodes 6 constituting the heat absorption side electrode group. These second heat transmitting members 9 are allowed to protrude to reach the space 4 outside the heat absorption side support member 2. The space 24 constitutes the second radiation space.

The first heat transmitting member 8 reaches the first radiation space 22 via a through hole provided in the heat radiation side support member 3. The second heat transmitting member 9 reaches the second radiation space 23 via a through-hole provided in the heat absorption side support member 2. Cooling fluids respectively flow in the first and the second heat radiation space 23. The integration structure of the electrodes 6 and 7 and the heat transmitting members 9 and 8 may be made the T-shape and L-shape as in the aforementioned embodiments. Further, the integrating method of the heat transmitting members 8 and 9 and the electrodes 7 and 6, the installation number, the construction materials, the shape and the like are the same as in the above embodiments.

A heat absorbing member 19 is provided at an end portion at an opposite side of the second heat transmitting member 8 integrated with the heat absorbing electrode 6. The heat absorbing member 19 constitutes a contact part with the component 16 to be cooled, and is constituted by an electrically insulating object, for example. The second heat transmitting member 9 is attached to the component 16 to be cooled via the heat absorbing member 19 to be electrically insulated. The second heat transmitting member 9 integrated with the heat absorbing electrode 6 functions as a heat transmitting medium to the heat absorbing electrode 6 from the heat absorbing member 19 when the thermoelectric element 21 is in operation, and functions as a heat radiating medium when the thermoelectric element 21 is not in operation. The first heat transmitting member 8 integrated with the heat radiating electrode 7 functions as a heat radiating medium when the thermoelectric element 21 is in operation.

An electronic component module 25 using the thermoelectric element 21 shown in FIG. 11 has the structure in which the thermoelectric element 21 is mounted on the component 16 to be cooled so that the heat absorbing member 19 provided at the end portions of the second heat transmitting members 9 abuts to the component 16 to be cooled. The placement structure of the thermoelectric element 21 is the structure in which the heat absorption side support member 2 is located at the side of the component to be cooled 16, and the second radiation space 24 is provided between the thermoelectric element 21 and the component 16 to be cooled. The second radiation space 24 is the space formed by the second heat transmitting members 9 as the leg portions. FIG. 11 shows the structure in which the heat radiating parts of the second heat transmitting members 9 are disposed between the component 16 to be cooled and cooling surfaces of the thermoelectric semiconductors 4 and 5.

In the thermoelectric element 21 as described above, direct-current is passed to the thermoelectric semiconductors 4 and 5 from the direct-current power supply 15, heat absorption occurs in the lower end portion side of the thermoelectric semiconductors 4 and 5, and heat radiation occurs to the upper end portion side. If the thermoelectric element 21 is energized and operated when the heat generation amount of the component 16 to be cooled increases, heat of the component 16 to be cooled is absorbed via the second heat transmitting members (heat transmitting media) 9, and the component 16 to be cooled is cooled. On the other hand, when the heat generation amount of the component 16 to be cooled is small, passing of electric current to the thermoelectric element 21 is cut off to make the thermoelectric element 21 out of operation. In the non-operation state of the thermoelectric element 21, the heat of the component 16 to be cooled is directly dissipated into the radiation space 24 from the heat absorbing member 19 and the second heat transmitting member 9.

In the thermoelectric element 21 of the aforementioned third embodiment, the second heat transmitting member 9 directly reaches the second heat radiation space 24 from the heat absorbing member 19, and therefore, the heat of the component 16 to be cooled can be directly dissipated into the second radiation space 24. Namely, the second heat transmitting member 9 functions as the heat radiating medium when the thermoelectric element 21 is not in operation. By such second heat transmitting member 9, heat radiating performance of the component 16 to be cooled when the thermoelectric element 21 is not in operation can be remarkably enhanced as compared with the conventional element structure.

Accordingly, even when the thermoelectric element 21 is operated as needed in accordance with the heat generation amount of the component 16 to be cooled, it is possible to keep cooling characteristic of the component 16 to be cooled. Further, as in the thermoelectric element 18 of the second embodiment, the fatigue breakdown or the like of the thermoelectric element 21 based on a thermal expansion difference between the thermoelectric element 21 and the component 16 to be cooled can be restrained by utilizing flexibility of the second heat transmitting member 9. The electronic component module 25 using the thermoelectric element 21 is preferably used in portable electronic apparatuses such as a notebook type PC, a tablet PC, PDA and a portable telephone as the first embodiment.

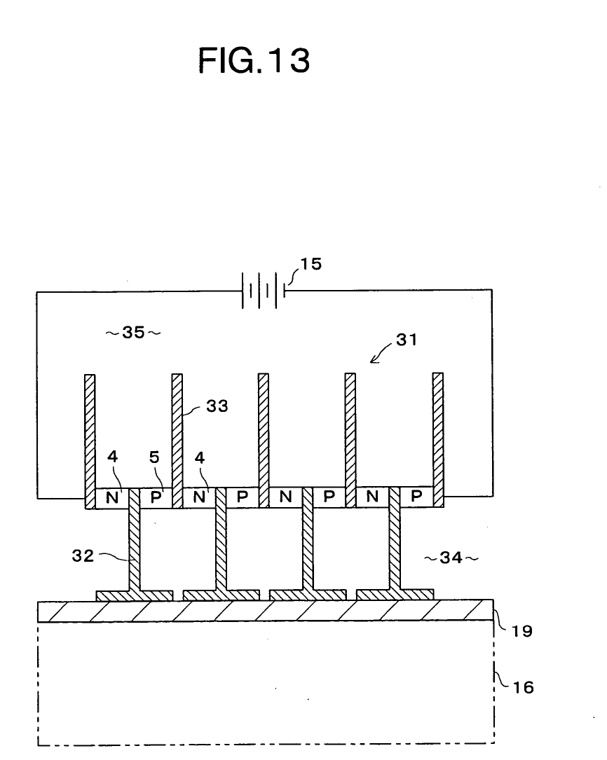

Each of the aforementioned embodiments is application of the thermoelectric element of the present embodiment to the π type structure, but the present invention is not limited to this. For example, as shown in FIG. 13, the thermoelectric element of the present invention can be applied to a thermoelectric element 31 in which the N type thermoelectric semiconductors 4 and the P type thermoelectric semiconductors 5 are disposed in the series structure.

In the thermoelectric element 31 shown in FIG. 13, a heat absorbing electrode 32 integrated with the second heat transmitting member is interposed in a part where an electric current passes toward the P type thermoelectric semiconductor 5 from the N type thermoelectric semiconductor 4. A heat radiating electrode 33 integrated with the first heat transmitting member is interposed in a part where the electric current passes toward the N type thermoelectric semiconductor 4 from the P type thermoelectric semiconductor 5.

The heat absorbing electrode 32 integrated with the second heat transmitting member is allowed to protrude toward a space 34 where one main surface of the thermoelectric element 31 is exposed, and the heat absorbing member 19 is integrally provided at a tip end thereof. The heat radiating electrode 33 integrated with the first heat transmitting member is allowed to protrude toward a space 35 where the other main surface of the thermoelectric element 31 is exposed. The first heat transmitting member and the second heat transmitting member are disposed in the radiation spaces 34 and 35 where cooling fluids respectively flow.

In the thermoelectric element 31 of such a structure, the heat of the component 16 to be cooled can be directly dissipated into the radiation space 34 as in the thermoelectric element 21 shown in FIG. 11. Accordingly, the component 16 to be cooled can be efficiently cooled not only when the thermoelectric element 31 is in operation but also when it is not in operation such as at the non-energized time, at the time of failure or the like. Namely, it is possible to restrain reduction in the cooling characteristic of the component 16 to be cooled when the thermoelectric element 31 is not in operation.

Industrial Applicability

As is obvious from the above embodiments, the thermoelectric element of the present invention restrains reduction in heat radiation characteristic of the component to be cooled when the thermoelectric element is not in operation. Accordingly, in cooling the component to be cooled by the thermoelectric element, it is possible to keep cooling characteristic of the component to be cooled not only when the thermoelectric element is in operation but also when it is not in operation. The thermoelectric element of the present invention is preferably used in an electronic component module, and the electronic component module of the present invention is preferably used in a portable electronic apparatuses.

1. A thermoelectric element, comprising:
a thermoelectric semiconductor group having N type thermoelectric semiconductors and P type thermoelectric semiconductors;
heat absorbing electrodes joined to one end part of said thermoelectric semiconductor group;
heat radiating electrodes joined to the other end part of said thermoelectric semiconductor group so that at least parts of said N type thermoelectric semiconductors and said P type thermoelectric semiconductors are alternately connected in series; and
heat transmitting members integrally provided to respective said heat absorbing electrodes and said heat radiating electrodes, disposed to be in contact with a cooling medium and having a function of radiating heat to said cooling medium.

2. A thermoelectric element according to claim 1,
wherein said heat absorbing electrodes are attached to an object to be cooled to be electrically insulated, and heat of said object to be cooled in a state in which said thermoelectric element is not energized is radiated to said cooling medium via said heat absorbing electrodes and said heat transmitting members.

3. A thermoelectric element according to claim 1,
wherein said heat transmitting members provided at said heat absorbing electrodes are attached to an object to be cooled to be electrically insulated, and have a function of directly radiating heat to said cooling medium and a function as part of said heat absorbing electrodes in combination, and heat of said object to be cooled in a state in which said thermoelectric element is not energized is radiated to said cooling medium via said heat transmitting members.

4. A thermoelectric element according to claim 1,
wherein in said heat transmitting member provided at said heat absorbing electrode, a region for radiating heat to said cooling medium exists at a position far from a cooling surface of said thermoelectric semiconductor group seen from an object to be cooled.

5. A thermoelectric element according to claim 1,
wherein in said heat transmitting member provided at said heat absorbing electrode, a region for radiating heat to said cooling medium exists between an object to be cooled and a cooling surface of said thermoelectric semiconductor group.

6. A thermoelectric element, comprising:
a support member;
a thermoelectric semiconductor group having N type thermoelectric semiconductors and P type thermoelectric semiconductors arranged along said support member;
heat absorbing electrodes joined to one end part of said thermoelectric semiconductor group;
heat radiating electrodes joined to the other end part of said thermoelectric semiconductor group so that at least parts of said N type thermoelectric semiconductors and said P type thermoelectric semiconductors are alternately connected in series; and
first heat transmitting members integrally provided to said heat radiating electrodes, and provided to protrude to a radiation space; and
second heat transmitting members integrally provided to said heat absorbing electrodes, and provided to protrude to said radiation space in a same direction as said first heat transmitting members.

7. A thermoelectric element according to claim 6,
wherein said support member is constituted of an electrical insulator, and is a heat absorbing support member constituting a contact part with an object to be cooled.

8. A thermoelectric element according to claim 7,
wherein said second heat transmitting members function as a heat radiating medium for dissipating heat of said object to be cooled into said radiation space when said thermoelectric element is not in operation.

9. A thermoelectric element according to claim 6, further comprising:
a heat absorbing member connected to end portions at an opposite side from said heat absorbing electrodes, of said second heat transmitting members to be capable of transmitting heat,
wherein said heat absorbing member constitutes a contact part with an object to be cooled.

10. A thermoelectric element according to claim 9,
wherein said second heat transmitting members have a function as a heat transmitting medium from said heat absorbing member to said heat absorbing electrode, and a function as a heat radiating medium from said heat absorbing member to said heat radiation space.

11. A thermoelectric element according to claim 10,
wherein said second heat transmitting members function as a heat radiating medium for dissipating heat of said object to be cooled into said radiation space when said thermoelectric element is not in operation.

12. A thermoelectric element, comprising:
a support member;
a thermoelectric semiconductor group having N type thermoelectric semiconductors and P type thermoelectric semiconductors arranged along said support member;
heat absorbing electrodes joined to one end part of said thermoelectric semiconductor group;
heat radiating electrodes joined to the other end part of said thermoelectric semiconductor group so that at least parts of said N type thermoelectric semiconductors and said P type thermoelectric semiconductors are alternately connected in series;
first heat transmitting members integrally provided to said heat radiating electrodes, and provided to protrude outside said heat radiating electrodes to be located at a first radiation space; and
second heat transmitting members integrally provided to said heat absorbing electrodes, and provided to protrude outside said heat absorbing electrodes to be located in a second radiation space; and
a heat absorbing member connected to end portions at an opposite side from said heat absorbing electrodes, of said second heat transmitting members to be capable of transmitting heat, and constituting a contact part with an object to be cooled.

13. A thermoelectric element according to claim 12,
wherein said second heat transmitting members have a function as a heat transmitting medium from said heat absorbing member to said heat absorbing electrode, and a function as a heat radiating medium from said heat absorbing member to said second heat radiation space.

14. A thermoelectric element according to claim 13,
wherein said second heat transmitting members function as a heat radiating medium for dissipating heat of said object to be cooled into said second radiation space when said thermoelectric element is not in operation.

15. An electronic component module, comprising:
a component to be cooled; and
a thermoelectric element according to claim 1 mounted on said component to be cooled.

16. An electronic component module, comprising:
a component to be cooled; and
a thermoelectric element according to claim 7 mounted on said component to be cooled so that said component to be cooled and said heat absorbing support member are in contact with each other.

17. A portable electronic apparatus, comprising an electronic component module according to claim 15.

18. A portable electronic apparatus, comprising an electronic component module according to claim 16.
